(19) United States
(12) Patent Application Publication
(10) Pub. No.: US 2006/0103438 A1
(43) Pub. Date: May 18, 2006

(54) Initialization signal generation apparatus for use in a semiconductor device

(75) Inventor: Khil Ohk Kang, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyunggi-do (KR)

(21) Appl. No.: 11/131,162

(22) Filed: May 17, 2005

(30) Foreign Application Priority Data
Nov. 15, 2004 (KR) 2004-92952

(51) Int. Cl. H03L 7/00

(52) U.S. Cl. 327/143

(57) ABSTRACT

There is provided an initialization signal generation apparatus for use in a semiconductor device. The apparatus comprises a voltage divider for dividing an external voltage into a plurality of divided voltages, a first initialization signal generator for producing a first initialization signal in response to a first divided voltage on a first node among the divided voltages, and a second initialization signal generator for providing a second initialization signal in response to a second divided voltage on a second node among the divided voltages. The initialization signal generation apparatus in the semiconductor in accordance with the present invention can prevent malfunction of the semiconductor device by a preclusion of the latch-up phenomenon which may arise when the high voltage level is lower than the external voltage level, by the high voltage generation circuit operated, prior to supplying the initialization signal to interrupt the short operation between the external power and the internal power, through supply of another initialization signal first, at an initialization step of the semiconductor device.

### BACKGROUND OF THE INVENTION

1. Field of the Invention

The present invention relates to an initialization signal generation apparatus in a semiconductor device; and, more particularly, to an initialization signal generation apparatus which is capable of preventing issuance of latch-up phenomenon by providing a different initialization signal to each of a high voltage generation circuit and a short circuit between an external power and an internal power in the semiconductor device.

2. Description of Related Art

In general, an initialization signal generation apparatus in a semiconductor device is in charge of initialization of the semiconductor chip. Meanwhile, to operate the semiconductor device, an external voltage VDD is supplied from the outside, where the level of the external voltage VDD rises up to a target level via a constant slope, starting from 0V.

At this time, if any of circuits in the semiconductor device inputs such external voltage VDD directly, then it causes a malfunction due to the rising external voltage. Thus, in order to prevent such a malfunction in the device, the semiconductor device comprises an initialing signal generation apparatus, which supplies it to each circuit when the external voltage reaches a stable level after rising to a certain level,

FIG. 1 shows a circuit diagram of a conventional initialization signal generation apparatus. Referring to this, operation of the conventional initialization signal generation apparatus will be explained below.

As shown in FIG. 1, a divided voltage is provided on a node A wherein the divided voltage is obtained by dividing an external voltage VDD by resistors R11 and R12. In response to the voltage from the node A, an NMOS M11 is operated.

For instance, if the external voltage is low and the voltage level on the node A is smaller than the threshold voltage Vt of the NMOS M11, then the NMOS M11 is in a turned-off state while a PMOS M12 is turned-on by a low level voltage VSS being applied to its gate. According to this, a node DET10 is pulled-up driven to the external voltage VDD level and thus the initialization signal ‘pwrup’ is in a low level state by passing through an inverter INV10.

However, if the external voltage VDD ascends and a voltage level on the node A is higher than the threshold voltage Vt of the NMOS M11, then the NMOS M11 is turned-on and the node DET10 is pull-down driven to the ground level. Based on this, the initialization signal ‘pwrup’ is transitioned from a low level to a high level and follows the external voltage VDD level since that time. Each circuit in the semiconductor device initiates to operate in response to the initialization signal ‘pwrup’ supplied thereto.

In the meantime, in the semiconductor device, to prevent a latch-up phenomenon which may arise when an internal voltage VPP of high level is applied to the bulk whereas the external voltage VDD is inputted to the source or drain, a short circuit is utilized to make a short between the external voltage VDD and the internal voltage VPP, prior to the initialization process step of the semiconductor device.

In a general case, an electric potential of the internal voltage VPP is higher than that of the external voltage VDD. However, before the initialization operation of the semiconductor device, the electric potential of the internal voltage VPP is lower than that of the external voltage VDD for any reasons such as non-pumping of the internal voltage VPP up to a proper electric potential. In this case, if the internal voltage VPP is applied to the n-type bulk and the external voltage VDD is provided to the source or drain, there is occurred a latch-up phenomenon which allows any current to flow between the bulk and the source (or drain) by the diode's turn-on effect. Thus, in order to solve this problem, the short circuit is necessary to short between the external voltage VDD and the internal voltage VPP, prior to the initialization operation of the semiconductor device.

Under the prior art apparatus, the short circuit is operated such that its short operation is interrupted in response to the initialization signal ‘pwrup’ provided by the initialization signal generation apparatus. That is, in the general short circuit, in case a level of the initialization signal ‘pwrup’ from the initialization signal generation apparatus is low, meaning a disabled state, the short state between the external power VDD and the internal power VPP is maintained, while, in case the initialization signal ‘pwrup’ is transited from a low level to a high level, the short state is cancelled.

However, since the prior art short circuit is operated in response to the initialization signal ‘pwrup’ from the initialization signal generation apparatus, there exists any phenomenon that the internal voltage VPP is temporarily lower than the external voltage VDD at the moment when a level of the initialization signal ‘pwrup’ is transited from a low level to a high level, as illustrated in FIG. 2. This results in the latch-up phenomenon as mentioned above.

Specifically, this problem is raised because the internal voltage VPP is temporarily lower than the external voltage VDD by not doing a high voltage generation operation by a high voltage generation circuit at a proper time, even when the short operation by the short circuit is interrupted by having the initialization signal ‘pwrup’ enabled. It is known that this latch-up phenomenon by the release of the short operation is occurs more frequently, particularly in a semiconductor memory device using an external voltage VDD smaller than 1.8V.

### SUMMARY OF THE INVENTION

It is, therefore, a primary object of the present invention to provide an initialization signal generation apparatus for use in a semiconductor device that is capable of preventing a malfunction of the semiconductor device by the preclusion of a latch-up phenomenon that may arise when an internal voltage level of high voltage is lower than an external voltage level upon an initialization of the semiconductor device.

In accordance with the present invention, there is provided an apparatus for generating initialization signals for use in a semiconductor device, the apparatus comprising: a voltage divider for dividing an external voltage into a plurality of divided voltages; a first initialization signal generator for producing a first initialization signal in response to a first divided voltage on a first node among the divided voltages; and a second initialization signal generator for providing a second initialization signal in response to a second divided voltage on a second node among the divided voltages.

Preferably, an electrical potential of the first divided voltage on the first node is higher than that of the second divided voltage on the second node.

Preferably, the voltage divider includes a first resistor coupled between an external power for supplying the external voltage and the first node; a second resistor connected between the first and the second nodes; and a third resistor prepared between the second node and the ground.

Preferably, the first initialization signal generator includes a first pull-down circuit for pull-down driving a third node in response to the first divided voltage from the first node; a first pull-up circuit for pull-up driving the third node to the external voltage level; and a first buffer for buffering a voltage signal from the third node to provide the first initialization signal.

Preferably, the first pull-down circuit is an NMOS that operates in response to the first divided voltage from the first node, and the first pull-up circuit is a PMOS that operates in response to the ground voltage.

Preferably, the first buffer is an inverter.

Preferably, the second initialization signal generator includes a second pull-down circuit for pull-down driving a fourth node in response to the second divided voltage from the second node; a second pull-up circuit for pull-up driving the fourth node to the external voltage level; and a second buffer for buffering a voltage signal from the fourth node to provide the second initialization signal.

Preferably, the second pull-down circuit is an NMOS that operates in response to the second divided voltage from the second node, and the second pull-up circuit is a PMOS that operates in response to the ground voltage.

Preferably, the second buffer is an inverter.

Preferably, the first initialization signal generator includes a first pull-down circuit for pull-down driving a third node in response to the first divided voltage from the first node; a first pull-up circuit for pull-up driving the third node to the external voltage level; and a first buffer for buffering a voltage signal from the third node to provide the first initialization signal, and wherein the second initialization signal generator includes a second pull-down circuit for pull-down driving a fourth node in response to the second divided voltage from the second node; a second pull-up circuit for pull-up driving the fourth node to the external voltage level; and a second buffer for buffering a voltage signal from the fourth node to provide the second initialization signal.

Preferably, an operation threshold voltage of the first pull-down circuit is identical to that of the second pull-down circuit.

Preferably, the first pull-down circuit is a first NMOS that operates in response to the first divided voltage from the first node, and the second pull-down circuit is a second NMOS that operates in response to the second divided voltage from the second node.

Preferably, the first initialization signal is supplied to a high voltage generation circuit for generating an internal voltage, and the second initialization signal is provided to a short circuit prepared between an external power and an internal power.

### BRIEF DESCRIPTION OF THE DRAWINGS

The above and other objects and features of the instant invention will become apparent from the following description of preferred embodiments taken in conjunction with the accompanying drawings, in which:

FIG. 1 is a circuit diagram illustrating a composition of an initialization signal generation apparatus in a semiconductor device according to the prior art;

FIG. 2 depicts a waveform of an external voltage and an internal voltage according to the prior art initialization signal generation apparatus;

FIG. 3 presents a block diagram showing the entire composition of an initialization signal generation apparatus, a high voltage generation circuit and a short circuit between an internal power and an external power to which the initialization signal is provided, contained in a semiconductor device in accordance with a preferred embodiment of the present invention;

FIG. 4 offers a detailed circuit diagram of the initialization signal generation apparatus in the semiconductor device in accordance with the preferred embodiment of the present invention;

FIG. 5 depicts a waveform of a first and a second initialization signals produced from the initialization signal generation apparatus of the present invention; and

FIG. 6 shows a waveform of the external voltage and the internal voltage provided in accordance with the initialization signal generation apparatus of the present invention.

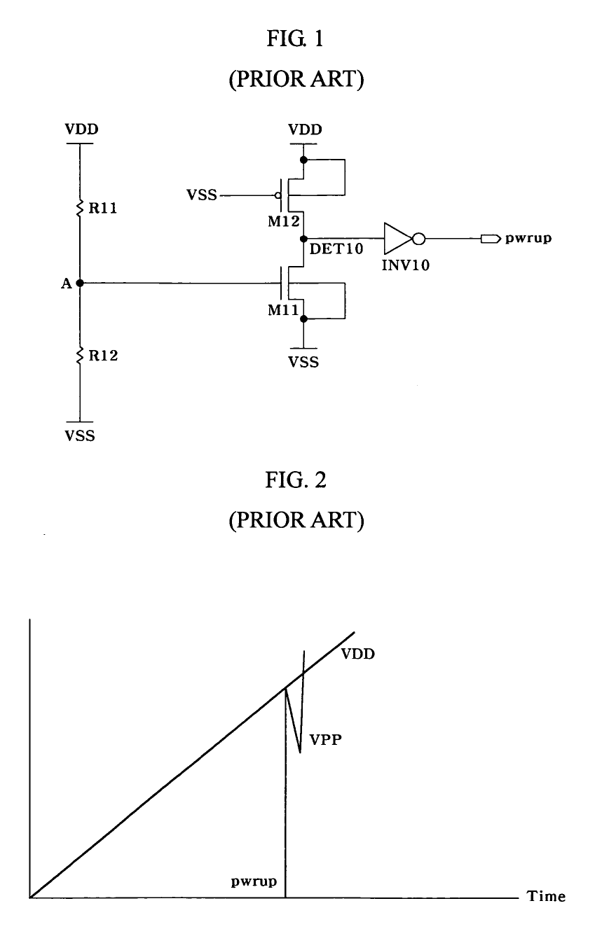

### DESCRIPTION OF THE PREFERRED EMBODIMENT

Hereinafter, preferred embodiments of the present invention will be explained in detail with reference to the accompanying drawings. First, it should be noted that since these embodiments are presented to illustrate the present invention merely, the right protection scope of the present invention is not limited to those embodiments.

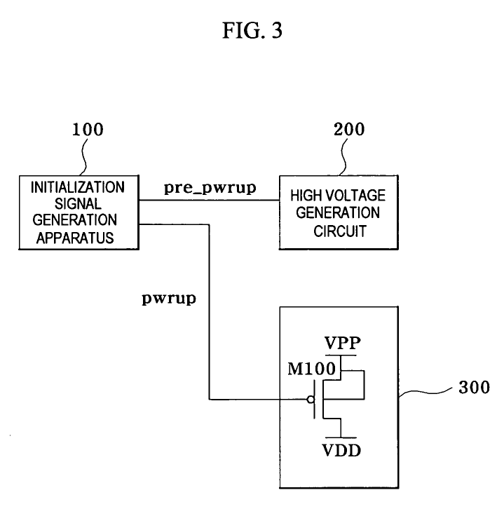

FIG. 3 shows a block diagram illustrating a whole composition of an initialization signal generation apparatus 100, a high voltage generation circuit 200 and a short circuit 300 between an internal power and external power source to which the initialization signal is supplied, contained in a semiconductor device in accordance with a preferred embodiment of the present invention.

As shown in FIG. 3, the initialization signal generation apparatus 100 of the present invention generates and provides a first and a second initialization signals, pre-‘pwrup’ and ‘pwrup’, to a high voltage generation circuit 200 for generating an internal voltage VPP which is a high voltage and a short circuit 300 prepared between an external power and an internal power, respectively. Herein, the first initialization signal pre-‘pwrup’ is a signal that is first enabled before the second initialization signal ‘pwrup’ is enabled. In the above, the high voltage generation circuit 200 receives the first initialization signal pre-‘pwrup’ that is first enabled as the external voltage VDD increases, and then produces the high voltage VPP first before the short circuit 300 stops the operation for a short between the external power VDD and the internal power VPP.

After that, even though the short operation by the short circuit 300 is interrupted by having the second initialization signal ‘pwrup’ enabled by a further increase of the external voltage VDD, there does not occur any phenomenon where the internal voltage VPP is temporarily lower than the external voltage VDD since it is already issued and continuously supplied from the high voltage generation circuit 200. Thus, the semiconductor device receiving the first and the second initialization signals from the initialization signal generation apparatus 100 of the present invention can prevent a latch-up phenomenon that may occur by lowering the internal voltage VPP below the external voltage VDD.

Now, a composition for realizing the conceptual principle of the present invention will be provided with reference to the accompanying drawings below.

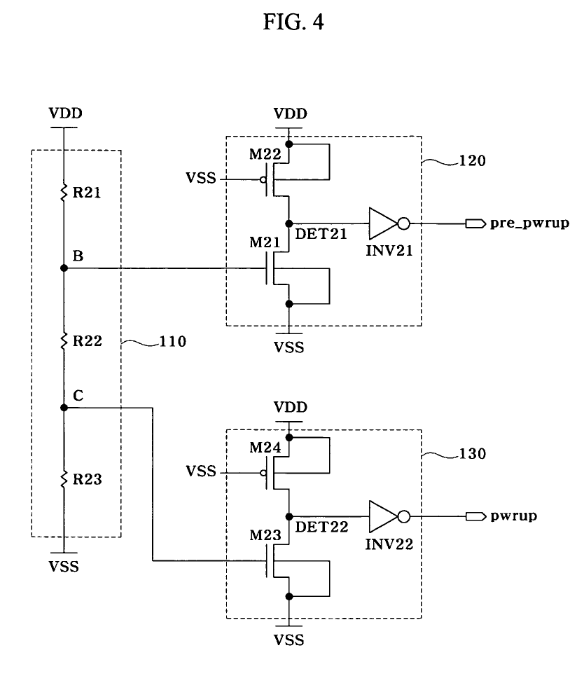

FIG. 4 depicts a detailed circuit diagram of the initialization signal generation apparatus 100 in accordance with the preferred embodiment of the present invention, wherein the present invention will be described in detail with reference to FIG. 4.

As shown in FIG. 4, the initialization signal generation apparatus 100 in the semiconductor device in accordance with a preferred embodiment of the present invention comprises a voltage divider 110 for dividing the external voltage VDD into a plurality of, for example, two divided voltages, a first initialization signal generator 120 for producing a first initialization signal pre-‘pwrup’ in response to a first divided voltage from the voltage divider 110 on a node B, and a second initialization signal generator 130 for generating a second initialization signal pwrup in response to a second divided voltage from the voltage divider 110 on a node C.

Specifically, the voltage divider 110 includes a resistor R21 coupled between the external power for supplying the external voltage VDD and the node B, a resistor R22 prepared between the nodes B and C, and a resistor R23 coupled between the node C and the ground VSS.

The first initialization signal generator 120 includes an NMOS M21 for pull-down driving a node DET21 in response to the first divided voltage from the node B, a PMOS M22 for pull-up driving the node DET21 to the external voltage VDD level, and a first inverter INV21 for buffering, specifically inverting a voltage signal from the node DET21 to provide the first initialization signal pre-‘pwrup’.

Further, the second initialization signal generator 130 includes an NMOS M23 for pull-down driving a node DET22 in response to the second divided voltage from the node C, a PMOS M24 for pull-up driving the node DET22 to the external voltage VDD level, and a second inverter INV22 for buffering, particularly inverting a voltage signal from the node DET22 to provide the second initialization signal ‘pwrup’.

In the above, it is set that an operation threshold voltage of the NMOS M21 is identical to that of the NMOS M23. And, as mentioned as, the first initialization signal pre-‘pwrup’ is supplied to the high voltage generation circuit 200, while the second initialization signal ‘pwrup’ is provided to the short circuit 300 connected between the external power and the internal power.

Hereinafter, an operation of this embodiment as structured above will be explained in detail.

First of all, if the external voltage VDD to the semiconductor device rises, a voltage level between the nodes B and C also rises. Passing through the voltage division through the resistors, R21, R22, and R23, included in the voltage divider 110, however, a voltage level on the B becomes higher than that on the node C. Meanwhile, in the preferred embodiment of the invention, it is designed that an operation threshold voltage Vt of the pull-down element NMOS M21 connected to the node B is the same as that of the pull-down element NMOS M23 coupled with the node C. Alternatively, of course, it may be designed that the operation threshold voltage of the element NMOS M21 is different from that of the element NMOS M23 according to the system condition or specification.

First, assuming that the external voltage VDD ascends starting from 0V, the elements NMOSs M21, M23 are in a turn-off state since the voltage levels from the nodes B, C does not reach the operation threshold voltage of the elements NMOSs M21, M23. Meanwhile, the PMOS M22 is turned-on on the basis of the ground VSS connected to its gate, thus making the node DET21 pull-up driven to the external voltage VDD level. This allows the first initialization signal pre-‘pwrup’ to remain in a low level state by an operation of the first inverter INV21. Likewise, the PMOS M24 is turned-on based on the ground VSS coupled with its gate, making the node DET22 pull-up driven to the external voltage VDD level. Also, this allows the second initialization signal ‘pwrup’ to be in a low level state by an operation of the second inverter INV22.

Accordingly, in the initial state that the external voltage VDD is applied, the first and the second initialization signals, pre-‘pwrup’, ‘pwrup’, are all in a low level state, thus the high voltage generation circuit 200 receiving these initialization signals is not in an operation state and the short circuit 300 conducts the short operation between the internal power and the external power.

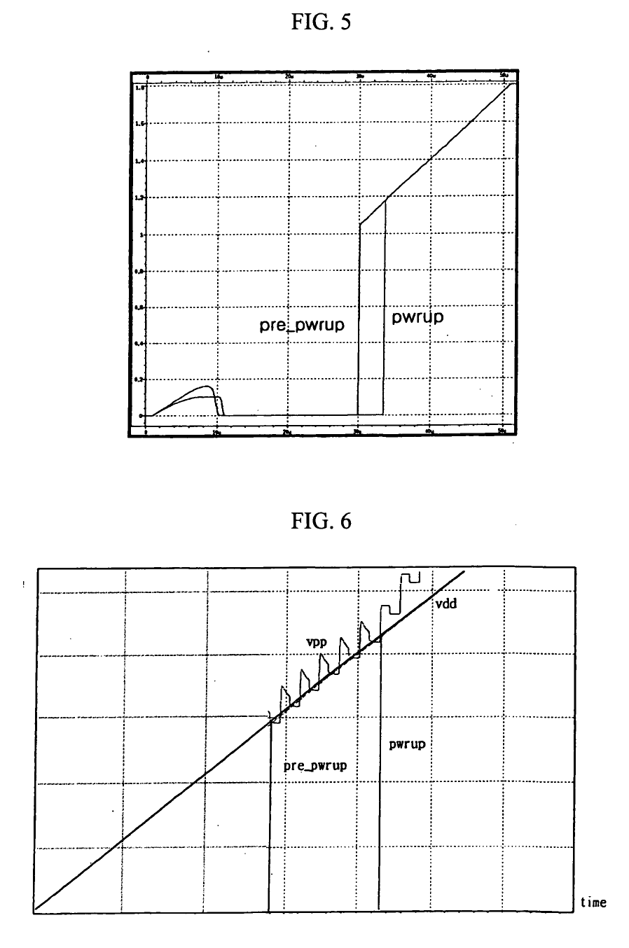

Thereafter, if the external voltage VDD rises continuously and the electric potential on the node B first reaches the threshold voltage Vt of the NMOS M21, then the NMOS M21 is turned-on and thus the node DET21 is pull-down driven to the ground. And, through the inversion operation in the first inverter INV21, the first initialization signal pre-‘pwrup’ is transitioned from low level to high level and then supplied to the high voltage generation circuit 200. Shown in FIG. 5 is the appearance that the first initialization signal pre-‘pwrup’ is first enabled as the external voltage VDD ascends.

In response to the first initialization signal pre-‘pwrup’ at a high level, the high voltage generation circuit 200 initiates a generation operation of the internal voltage VPP with high voltage level. Thus, since high voltage VPP is provided through a voltage pumping operation by the high voltage generation circuit 200 while the internal power VPP stays in a short state with the external power VDD, it continues to maintain a stable voltage level independently from the external voltage VDD. On the other hand, the voltage level on the node C is lower than that of the node B and does not reach the threshold voltage of the NMOS M23, thus the second initialization signal ‘pwrup’ continues to maintain a low level.

Next, referring back to FIG. 4, if the external voltage VDD further ascends and the electric potential of the NMOS M23 also reaches the threshold voltage Vt, then the NMOS M23 is turned-on. By this, the node DET22 is pull-down driven to the ground. And, through an inversion operation by the second inverter INV22, the second initialization signal ‘pwrup’ is also transitioned from a low level to a high level and then supplied to the short circuit 300. FIG. 5 shows the appearance that the second initialization signal ‘pwrup’ is also enabled as the external voltage VDD further rises.

In response to the second initialization signal ‘pwrup’ of a high level, the short circuit 300 stops the short operation between the external power and the internal power. According to this, the internal voltage VPP is separated from the external voltage VDD.

Contrary to the prior art, in the preferred embodiment of the present invention, there is no phenomenon where the internal voltage VPP level is temporarily lower than the external voltage VDD level, where the latch-up problem does not occur. In other words, since the high voltage VPP is provided to the internal voltage VPP end from the high voltage generator 200 that was already turned-on despite the short state between the internal power and the external power is released, there exists no latch-up phenomenon that may arise when the internal voltage VPP is lower than the external voltage VDD.

Turning now to FIG. 6, there is shown a waveform of the external voltage and the internal voltage in accordance with the initialization signal generation apparatus of the present invention. As can be seen from FIG. 6, there arises no latch-up phenomenon since the internal voltage VPP is not lower than the external voltage VDD, even when the second initialization signal ‘pwrup’ is enabled and the short operation is then interrupted.

As mentioned above, by making the first initialization signal pre-‘pwrup’ enabled first also by having the internal voltage VPP end inputs a stable high voltage from the high voltage generation circuit 200 before the external voltage VDD rises and the short operation by the short circuit 300 is interrupted by the second initialization signal ‘pwrup’, the initialization signal generation apparatus of the present invention can prevent the latch-up phenomenon by making sure that the internal voltage VPP with such a high voltage level is not lower than the external voltage VDD although the short operation by the short circuit 300 is later interrupted.

As a result, the initialization signal generation apparatus in the semiconductor in accordance with the present invention can prevent a malfunction of the semiconductor device by a preclusion of the latch-up phenomenon which may arise when the high voltage level is lower than the external voltage level, by making the high voltage generation circuit operated, prior to supplying the initialization signal to interrupt the short operation between the external power and the internal power, through a supply of another initialization signal first, at an initialization step of the semiconductor device.

While the present invention has been described with respect to the particular embodiments, it will be apparent to those skilled in the art that various changes and modifications may be made without departing from the spirit and scope of the invention as defined in the following claims.

What is claimed is:

1. An apparatus for generating initialization signals for use in a semiconductor device, the apparatus comprising:
a voltage divider for dividing an external voltage into a plurality of divided voltages;
a first initialization signal generator for producing a first initialization signal in response to a first divided voltage on a first node among the divided voltages; and
a second initialization signal generator for providing a second initialization signal in response to a second divided voltage on a second node among the divided voltages.

2. The apparatus as set force in claim 1, wherein an electrical potential of the first divided voltage on the first node is higher than that of the second divided voltage on the second node.

3. The apparatus as set force in claim 2, wherein the voltage divider includes:
a first resistor coupled between an external power for supplying the external voltage and the first node;
a second resistor connected between the first and the second nodes; and
a third resistor prepared between the second node and the ground.

4. The apparatus as set force in claim 1, wherein the first initialization signal generator includes:
a first pull-down circuit for pull-down driving a third node in response to the first divided voltage from the first node;
a first pull-up circuit for pull-up driving the third node to the external voltage level; and
a first buffer for buffering a voltage signal from the third node to provide the first initialization signal.

5. The apparatus as set force in claim 4, wherein the first pull-down circuit is an NMOS that operates in response to the first divided voltage from the first node, and the first pull-up circuit is a PMOS that operates in response to the ground voltage.

6. The apparatus as set force in claim 4, wherein the first buffer is an inverter.

7. The apparatus as set force in claim 1, wherein the second initialization signal generator includes:
a second pull-down circuit for pull-down driving a fourth node in response to the second divided voltage from the second node;
a second pull-up circuit for pull-up driving the fourth node to the external voltage level; and
a second buffer for buffering a voltage signal from the fourth node to provide the second initialization signal.

8. The apparatus as set force in claim 7, wherein the second pull-down circuit is an NMOS that operates in response to the second divided voltage from the second node, and the second pull-up circuit is a PMOS that operates in response to the ground voltage.

9. The apparatus as set force in claim 7, wherein the second buffer is an inverter.

10. The apparatus as set force in claim 1, wherein the first initialization signal generator includes:
a first pull-down circuit for pull-down driving a third node in response to the first divided voltage from the first node;
a first pull-up circuit for pull-up driving the third node to the external voltage level; and
a first buffer for buffering a voltage signal from the third node to provide the first initialization signal, and
wherein the second initialization signal generator includes:
a second pull-down circuit for pull-down driving a fourth node in response to the second divided voltage from the second node;
a second pull-up circuit for pull-up driving the fourth node to the external voltage level; and
a second buffer for buffering a voltage signal from the fourth node to provide the second initialization signal.

11. The apparatus as set force in claim 10, wherein an operation threshold voltage of the first pull-down circuit is identical to that of the second pull-down circuit.

12. The apparatus as set force in claim 11, wherein the first pull-down circuit is a first NMOS that operates in response to the first divided voltage from the first node, and the second pull-down circuit is a second NMOS that operates in response to the second divided voltage from the second node.

13. The apparatus as set force in claim 1, wherein the first initialization signal is supplied to a high voltage generation circuit for generating an internal voltage, and the second initialization signal is provided to a short circuit prepared between an external power and an internal power.
